(19) United States
(12) Patent Application Publication
(10) Pub. No.: US 2008/0230828 A1
(43) Pub. Date: Sep. 25, 2008

(54) GATE STRUCTURE OF A NON-VOLATILE MEMORY DEVICE AND METHOD OF MANUFACTURING SAME

(75) Inventor: Dae-Hyun JANG, Seoul (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-do (KR)

(21) Appl. No.: 12/113,883

(22) Filed: May 1, 2008

Related U.S. Application Data
(62) Division of application No. 11/321,645, filed on Dec. 28, 2005.

(30) Foreign Application Priority Data
Dec. 28, 2004 (KR) 2004-113757

(51) Int. Cl. H01L 49/00

(52) U.S. Cl. 257/321; 257/E49.001

(57) ABSTRACT

A non-volatile memory device includes a substrate that is divided into a field region and an active region by isolation layer patterns. The active region has an active trench for increasing an effective area of the active region. A tunnel oxide layer is formed on the active region. A floating gate pattern is formed on the tunnel oxide layer to fill up the active trench. A dielectric layer pattern is formed on the floating gate pattern. A control gate pattern is formed on the dielectric layer pattern. Thus, the non-volatile memory device has an increased effective area of the active region so that the non-volatile memory device may have improved operational characteristics.

### CROSS-REFERENCE TO RELATED APPLICATIONS

This application is a Divisional of U.S. patent application Ser. No. 11/321,645, filed on Dec. 28, 2005, now pending, and claims priority under 35 U.S.C. § 119 to Korean Patent Application No. 2004-113757, filed on Dec. 28, 2004, both of which are incorporated by reference in their entirety for all purposes.

### BACKGROUND

1. Technical Field

This disclosure relates to semiconductor devices and their methods of manufacture. More particularly, the disclosure relates to a gate structure of a transistor that is employed in a semiconductor memory device, and a method of forming the gate structure.

2. Description of the Related Art

Generally speaking, semiconductor memory devices are classified as either volatile memory devices, which lose data over time, or non-volatile memory devices, which continuously possess data regardless of time. Examples of volatile memory devices include dynamic random access memory (DRAM) and static random access memory (SRAM), while examples of non-volatile memory devices include flash memory.

A non-volatile memory device such as the flash memory device is classified as either an NOR type flash memory device or an NAND type flash memory device depending on what circuits are employed in the non-volatile memory device.

A NAND type flash memory device includes unit strings in which n numbers of cell transistors are connected to one another in series. The unit strings are connected in parallel to a bit line and a ground line. An advantage of the NAND type flash memory device is that it is easily integrate.

In a NOR type flash memory device each of the cell transistors is connected in parallel to a bit line and a ground line. An advantage of the NOR type flash memory device is that is may be operated rapidly.

A unit cell of a flash memory device includes a vertically stacked gate structure with a floating gate electrode. In particular, the vertically stacked gate structure includes a tunnel oxide layer, a floating gate electrode, a dielectric layer, and a control gate electrode that are sequentially stacked.

In general, a floating gate electrode in a gate structure of the NAND type flash memory device is formed in a linear active region. When the size of the floating gate electrode in the active region is no less than a predetermined size, a cell current and a coupling ratio are maintained. To increase the operation speed of the flash memory device by increasing the cell current, shortening a channel length and widening a width of the active region are required.

However, as design rules for a memory cell are reduced, the width of the active region is narrowed so much that a Fowler-Nordheim (F-N) tunneling effect is not generated sufficiently. Furthermore, when the flash memory device is operated, the cell current decreases and the operation speed of the flash memory device is reduced. Furthermore, since the distribution characteristics of the cell current deteriorates, the data in the flash memory device may be excessively erased.

The SRAM device and the DRAM device include a transistor that is different from that of the flash memory device. The transistor of the SRAM device and the DRAM device correspond to a MOS transistor that includes a gate insulation layer, a gate electrode, and source/drain regions. However, in the transistor of the SRAM device and the DRAM device, as a width of an active region is narrowed, the operation speed of the transistor is reduced.

### SUMMARY

The present invention provides a non-volatile memory device that is capable of sufficiently generating an F-N tunneling effect.

The present invention also provides a method of manufacturing the above-mentioned non-volatile memory device.

The present invention still also provides a gate structure of a transistor that has a rapid operation speed.

The present invention still also provides a method of forming the above-mentioned gate structure.

### BRIEF DESCRIPTION OF THE DRAWINGS

FIG. 1 is a perspective diagram illustrating a non-volatile memory device according to some embodiments of the invention.

FIGS. 2 to 8 are sectional diagrams illustrating a method of manufacturing the non-volatile memory device of FIG. 1.

FIG. 9 is a perspective diagram illustrating the method of manufacturing the non-volatile memory device of FIG. 1.

FIG. 10 is a perspective diagram illustrating a non-volatile memory device according to some other embodiments of the invention.

FIGS. 11 to 13 are sectional diagrams illustrating a method of manufacturing the non-volatile memory device of FIG. 10.

FIG. 14 is a perspective diagram illustrating a non-volatile memory device in accordance with some other embodiments of the invention.

FIGS. 15 to 19 are sectional diagrams illustrating a method of manufacturing the non-volatile memory device of FIG. 14.

FIG. 20 is a perspective diagram illustrating the method of manufacturing the non-volatile memory device of FIG. 14.

FIG. 21 is a plan diagram illustrating a gate structure of a transistor in an SRAM device in accordance with some embodiments of the invention.

FIG. 22 is a sectional diagram taken along the line I-I′ of FIG. 21.

FIGS. 23 to 26 are sectional diagrams illustrating a method of manufacturing the gate structure of FIG. 22.

FIG. 27 is a sectional diagram illustrating a gate structure of a transistor in accordance with some embodiments of the invention.

FIG. 28 is a sectional diagram illustrating a method of forming the gate structure in FIG. 27.

### DETAILED DESCRIPTION

The teachings of the invention are described below with reference to the accompanying drawings, in which embodiments of the invention are shown. The teachings of the invention may, however, be embodied in many different forms and should not be construed as limited to the embodiments set forth herein; rather, these exemplary embodiments are provided so that this disclosure is thorough and complete, and conveys the scope of the invention to those skilled in the art. In the drawings, the thickness of layers and regions are exaggerated for clarity. Like reference numerals refer to similar or identical elements throughout. It will be understood that when an element such as a layer, a region or a substrate is referred to as being “on” or “onto” another element, it can be directly on the other element or intervening elements may also be present.

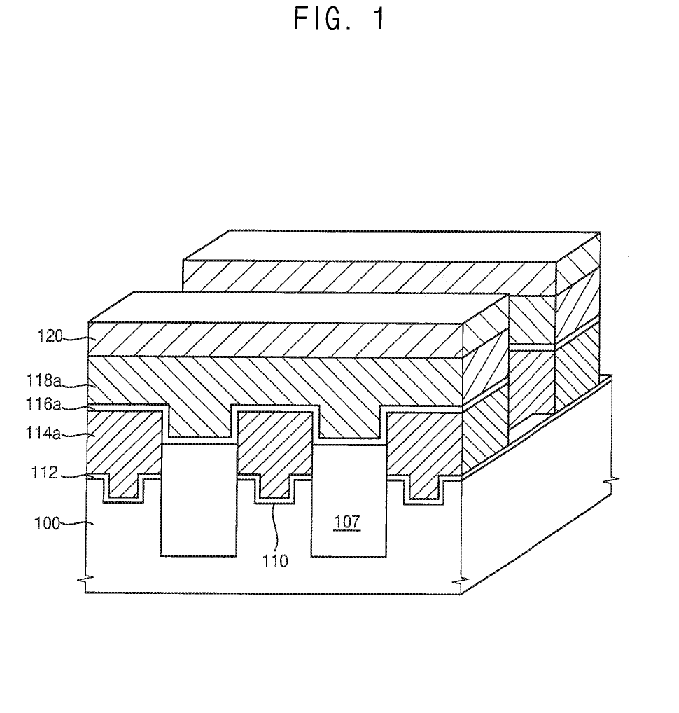

FIG. 1 is a perspective diagram illustrating a non-volatile memory device according to some embodiments of the invention.

Referring to FIG. 1, a non-volatile memory device includes a semiconductor substrate 100 that is divided into field regions and active regions. In particular, isolation trenches are formed at a surface portion of the semiconductor substrate 100. The isolation trenches are filled with isolation layer patterns 107 to define the field regions and the active regions. Here, the isolation layer patterns 107 may include silicon oxide. Furthermore, active trenches 110 are formed at a central surface portion of the active region. Thus, the active trenches 110 have a bottom surface that is lower than an upper surface of the active region, that is, lower than an upper surface of the semiconductor substrate 100. The active trenches 110 increase the effective area of the active region.

The isolation layer patterns 107 and the active regions are linear structures that extend lengthwise in a first direction. In addition, the active trenches 110 are also linear structures that extend lengthwise in the first direction.

At least one active trench 110 may be provided in a central portion of the active region. Since the area of the active region is very small, it is difficult to provide one active region with several active trenches 110. Thus, according to the illustrated embodiments, each active region has one active trench 110. Here, the active trench 110 is spaced apart from the isolation layer patterns 107. Thus, upper portions of the active region between the isolation layer patterns 107 and the active trench 110 protrude upwardly from the rest of the active region and the effective area of the active region is increased.

The isolation layer patterns 107 have an uppermost surface that is higher than the uppermost surface of the semiconductor substrate 100.

A tunnel oxide layer 112 is disposed on the upper surface of the active region, and on a side surface and a bottom surface of the active trench 110. The tunnel oxide layer 112 may include silicon oxide. Because the active trench 110 adds increased surface area to the active region, the tunnel oxide layer 112 has an area that is greater than that of a conventional tunnel oxide layer that is formed on a flat active region. Thus, when charges are inputted/outputted into/from a floating gate pattern 114a from the semiconductor substrate 100 to perform programming process or erasing process of the flash memory device, a sufficient F-N tunneling effect generated.

The floating gate pattern 114a is disposed on the tunnel oxide layer 112 to fill the active trench 110. In particular, a space between the isolation layer patterns 107 is fully filled with the floating gate pattern 114a. The floating gate pattern 114a may include polysilicon that is doped with impurities.

The floating gate pattern 114a has an upper surface that is higher than that of the isolation layer patterns 107. Furthermore, the floating gate pattern 114a is not disposed on the isolation layer patterns 107.

A dielectric layer pattern 116a is disposed both on the floating gate pattern 114a and on the isolation layer patterns 107. That is, the dielectric layer pattern 116a is disposed on the upper surfaces of the floating gate pattern 114a and the isolation layer patterns 107, as well as on the upper side surfaces of the floating gate pattern 114a, following the profile defined by the floating gate pattern 114a and the isolation layer patterns 107.

Because a contact area between the dielectric layer pattern 116a and the floating gate pattern 114a is increased compared to the contact area between flat layers, a capacitance between the dielectric layer pattern 116a and a control gate pattern 118a is also increased. As a result, the coupling ratio of the non-volatile memory device may be improved.

The dielectric layer pattern 116a may include stacked layers of silicon oxide/silicon nitride/silicon oxide (ONO). Alternatively, the dielectric layer pattern 116a may include a material having a high dielectric constant, which is capable of reducing a leakage current between the dielectric layer patterns 116a, with a thin equivalent oxide thickness (EOT).

The material having a high dielectric constant may include one or more metal oxide materials. Examples of metal oxide materials include HfO₂, ZrO₂, Ta₂O₅, Y₂O₃, Nb₂O₅, Al₂O₃, TiO₂, CeO₂, In₂O₃, RuO₂, MgO, SrO, B₂O₃, SnO₂, PbO, PbO₂, Pb₃O₄, V₂O₃, La₂O₃, Pr₂O₃, Sb₂O₃, Sb₂O₅, and CaO, etc. The metal oxide materials may be used alone, or in combination with other metal oxide materials and layers of the dielectric pattern 116a. For example, the dielectric layer pattern 116a may include sequentially stacked layers like a silicon oxide layer, a silicon nitride layer, and a layer of material having a high dielectric constant.

The control gate pattern 118a is disposed on the dielectric layer pattern 116a. The control gate pattern 118a may include polysilicon doped with impurities or a metal. The control gate pattern 118a has a linear shape that extends lengthwise in a second direction, the second direction substantially perpendicular to the first direction.

A hard mask pattern 120 is disposed on the control gate pattern 118a. The hard mask pattern 120 may include silicon nitride.

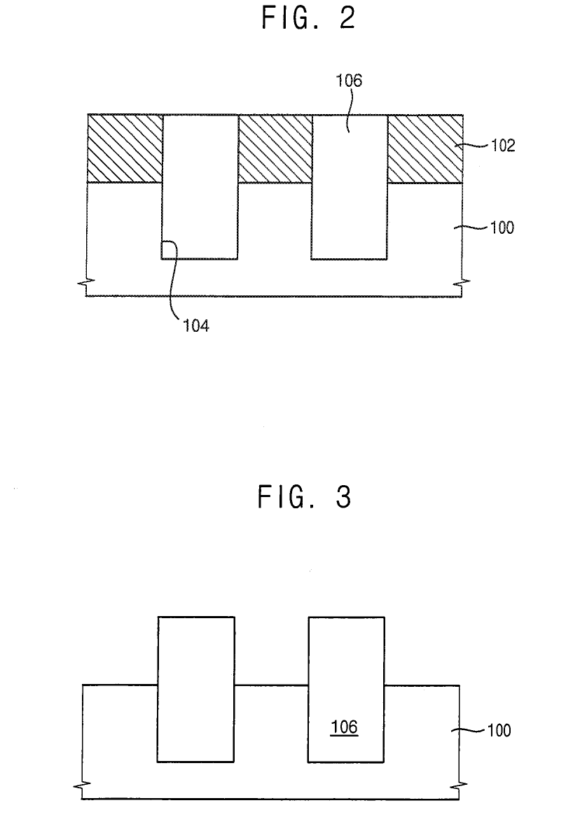

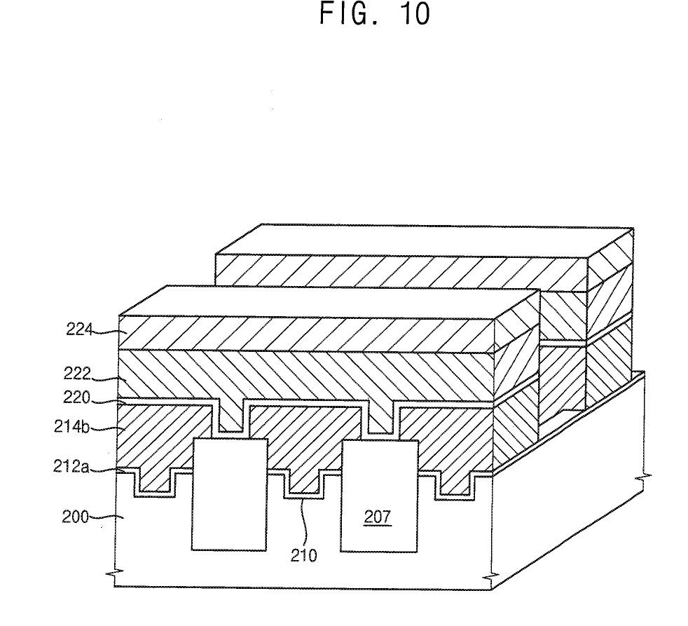

FIGS. 2 to 8 are sectional diagrams illustrating a method of manufacturing the non-volatile memory device of FIG. 1. FIG. 9 is a perspective diagram illustrating the method of manufacturing the non-volatile memory device of FIG. 1.

Referring to FIG. 2, a buffer oxide layer (not shown) is formed on the semiconductor substrate 100. A first hard mask pattern 102 for selectively masking the active region is formed on the buffer oxide layer. The first hard mask pattern 102 functions as an etching mask for forming the isolation trenches 104. The first hard mask pattern 102 may include silicon nitride. The first hard mask pattern 102 has a linear shape that extends lengthwise in the first direction.

Here, the first hard mask pattern 102 defines a gap for molding a floating gate electrode in a following process. Thus, the first hard mask pattern 102 has an upper surface that is higher than that of the floating gate electrode. Furthermore, the first hard mask pattern 102 preferably has a thickness of no less than about 500 Å.

The buffer oxide layer and the semiconductor substrate 100 are selectively etched using the first hard mask pattern 102 as an etching mask to form the isolation trenches 104. To cure etching damages, an oxide layer (not shown) may be formed on the surfaces of the isolation trenches 104.

An isolation layer (not shown) is formed on the oxide layer and the first hard mask pattern 102 to fill up the isolation trenches 104. Examples of the isolation layer include an oxide layer such as TEOS, USG, SOG, HDP-CVD, etc.

The isolation layer is planarized by a chemical mechanical polishing (CMP) process until the hard mask pattern 102 is exposed to form preliminary isolation layer patterns 106 in the isolation trenches 104.

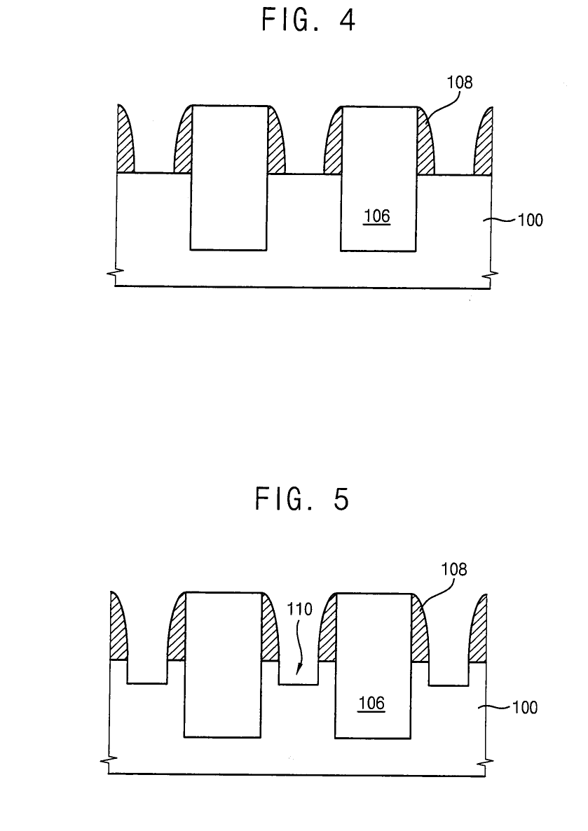

Referring to FIG. 3, the first hard mask pattern 102 and the buffer oxide layer are removed to expose the upper surface of the semiconductor substrate 100. Some of the buffer oxide layer may remain on the semiconductor substrate 100. After the first hard mask pattern 102 is removed, a gap between the preliminary isolation layer patterns 106 is formed. In the illustrated embodiments, the first hard mask pattern 102 is removed by a wet etching process using a phosphorous acid solution.

Referring to FIG. 4, an insulation layer (not shown) for a spacer is formed on the upper surface and the side surfaces of the preliminary isolation layer patterns 106 and the exposed upper surface of the semiconductor substrate 100. To prevent the insulation layer from filling up the gap, the insulation layer preferably has a thickness that is less than half the width of the exposed upper surface of the semiconductor substrate 100. The insulation layer may include silicon nitride.

The insulation layer is converted into a spacer with the following process. The spacer functions as a mask for etching the semiconductor substrate 100. Thus, to use the insulation layer as the mask, the insulation layer must have a proper thickness. That is, when the insulation layer has a thickness less than the proper thickness, the insulation layer does not function as the mask. On the other hand, when the insulation layer has a thickness greater than the proper thickness, the insulation layer completely fills the gap between the preliminary isolation layer patterns 106.

Although the thickness of the insulation layer varies in accordance with the width of the exposed upper surface of the semiconductor substrate 100 between the preliminary isolation layer patterns 106, the insulation layer may have a thickness of about 100 Å to about 500 Å, and preferably has a thickness of about 200 Å to about 400 Å.

The insulation layer is anisotropically etched until the semiconductor substrate 100 is exposed to form the spacers 108 on sidewalls of the preliminary isolation layer patterns 106. The spacers 108 serve as an etching mask for etching a central surface portion of the semiconductor substrate 100.

In order to use the spacers 108 as an etching mask, the spacers 108 should have a proper height from the upper surface of the semiconductor substrate 100. When the spacers 108 have a height that is less than the proper height, the spacers 108 are completely removed during the anisotropic etching process and the spacers 108 will not function as an etching mask. Although the height of the spacers 108 varies in accordance with an etched depth of the semiconductor substrate 100, the spacers 108 may have a height that is about 500 Å from the upper surface of the semiconductor substrate 100.

The portions of the preliminary isolation layer patterns 106 that protrude from the upper surface of the semiconductor substrate 100 have a thickness that is substantially identical or similar to the thickness of the first hard mask pattern 102. Since the first hard mask pattern 102 had a thickness of no less than about 500 Å, the protruding portions of the preliminary isolation layer patterns 106 have a thickness of no less than about 500 Å. Therefore, in order to use the spacers 108 as the etching mask, the spacers 108 should have a height of no less than about 500 Å.

Referring to FIG. 5, the semiconductor substrate 100 is partially etched using the spacers 108 as an etching mask to form the active trenches 110 at the central surface portion of the semiconductor substrate 100. Thus, the active region includes a central portion beneath the active trenches 110, and an edge portion between the central portion and the preliminary isolation layer patterns 106. Since the central portion is positioned beneath the active trenches 110, the edge portion has an upper surface that is higher than that of the central portion.

Because the active trenches 110 are included in the active region, the effective width of the active region is increased compared to that of an active region that has a flat upper surface.

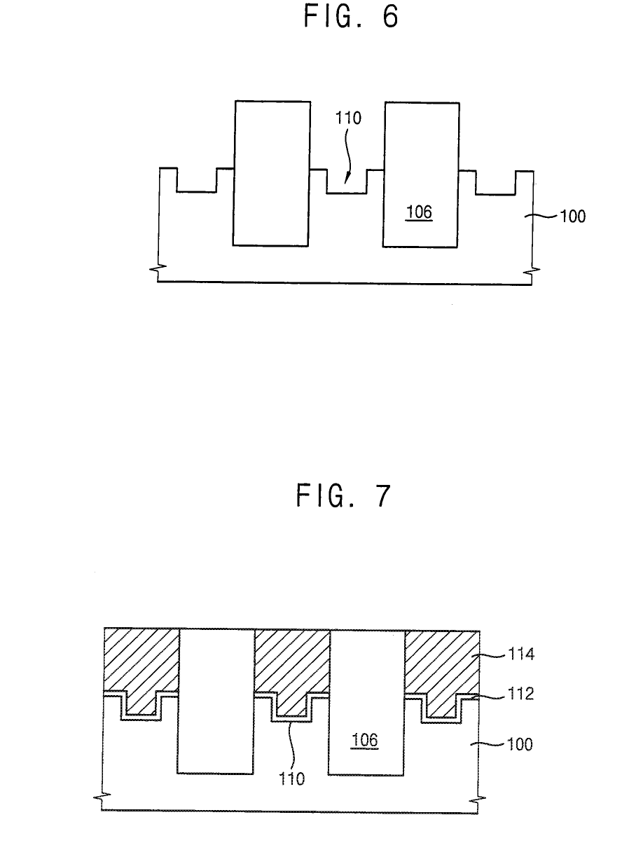

Referring to FIG. 6, the spacers 108 are removed to expose the upper surface of the active region. Here, the spacers 108 may be removed by a wet etching process using a phosphorous acid solution. After the spacers 108 are removed, a gap where the floating gate pattern will be subsequently formed exists between the preliminary isolation layer patterns 106.

In alternative embodiments of the invention, the preliminary isolation layer patterns 106 may be etched to shorten the height of the preliminary isolation layer patterns. In particular, the preliminary isolation layer patterns 106 may be etched using a wet etching process with a hydrofluoric acid solution. The wet etching process for removing the preliminary isolation layer patterns 106 may be carried out when the preliminary isolation layer patterns 106 have an upper surface that is excessively higher than that of the floating gate electrode. Furthermore, the wet etching process for shortening the preliminary isolation layer patterns 106 may be performed before removing the spacers 108.

Referring to FIG. 7, the tunnel oxide layer 112 is formed on the active region. The semiconductor substrate 100 may be thermally oxidized to form the tunnel oxide layer 112. Although a thickness of the tunnel oxide layer 112 varies in accordance with characteristics of a transistor, the tunnel oxide layer 112 preferably has a thickness of about 50 Å to about 200 Å.

A first conductive layer (not shown) is then formed on the preliminary isolation layer patterns 106 and the tunnel oxide layer 112. The first conductive layer may include polysilicon doped with impurities.

The first conductive layer is planarized by a CMP process until the preliminary isolation layer patterns 106 are exposed, thereby forming a preliminary floating gate pattern 114.

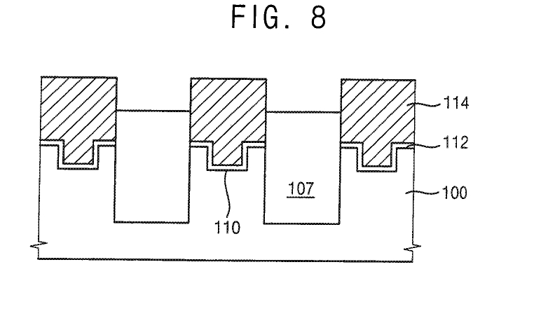

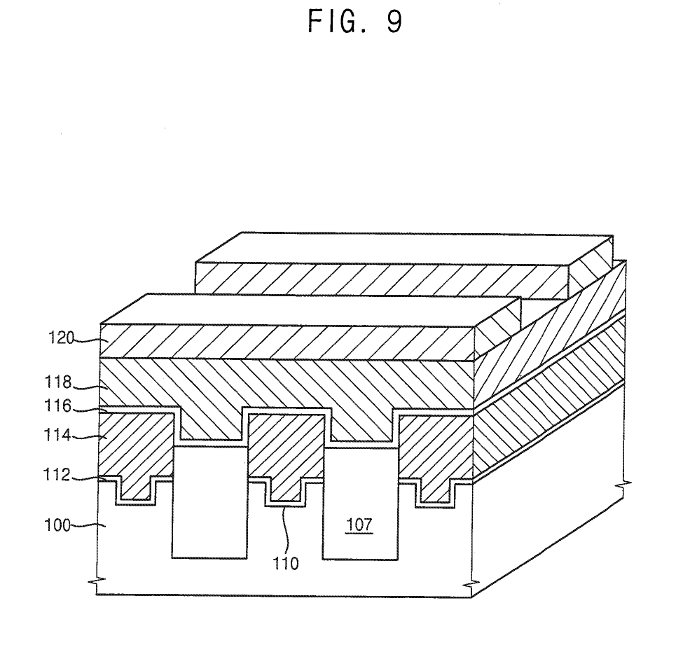

Referring to FIG. 8, the preliminary isolation layer patterns 106 are partially etched to expose an upper side surface of the preliminary floating gate pattern 114, thereby forming the isolation layer patterns 107. The isolation layer patterns 107 have an upper surface that is disposed higher than an upper surface of the active region.

Referring to FIG. 9, a dielectric layer 116 is formed on upper surfaces of the preliminary floating gate pattern 114 and the isolation layer patterns 107, as well as the upper side surface of the preliminary floating gate pattern 114, along the profile defined by the preliminary floating gate patterns 114 and the isolation layer patterns 107.

The dielectric layer 116 may include a multi-layer of ONO. Alternatively, the dielectric layer 116 may include a metal oxide material having a high dielectric constant. Examples of the metal oxide material include HfO₂, ZrO₂, Ta₂O₅, Y₂O₃, Nb₂O₅, Al₂O₃, TiO₂, CeO₂, In₂O₃, RuO₂, MgO, SrO, B₂O₃, SnO₂, PbO, PbO₂, Pb₃O₄, V₂O₃, La₂O₃, Pr₂O₃, Sb₂O₃, Sb₂O₅, CaO, etc. The metal oxide materials may be used alone or in combination with one or more of the materials specified above. For example, the dielectric layer 116 may have a stacked structure that includes a silicon oxide layer, a silicon nitride layer, and a metal oxide material having a high dielectric constant.

A second conductive layer 118 is then formed on the dielectric layer 116. The second conductive layer 118 may include a doped polysilicon material or a metal material. The second hard mask pattern 120 for patterning a control gate is formed on the second conductive layer 118. The second hard mask pattern 120 has a linear shape that extends lengthwise in the second direction, the second direction substantially perpendicular to the first direction.

Referring now to FIG. 1, the second conductive layer 118, the dielectric layer 116 and the preliminary floating gate pattern 114 are sequentially etched using the second hard mask layer pattern 120 as an etching mask to form the floating gate pattern 114a, the dielectric layer pattern 116a, and the control gate pattern 118a. The floating gate pattern 114a has an isolated shape in the direction of the active region. In other words, along the first direction each of the floating gate patterns 114a is separated from an adjacent floating gate pattern. Furthermore, the control gate pattern 118a has a linear shape that extends lengthwise in a second direction, the second direction substantially perpendicular to the first direction.

FIG. 10 is a perspective diagram illustrating a non-volatile memory device according to some other embodiments of the invention.

The non-volatile memory device of the illustrated embodiments includes elements that are substantially identical, with the exception of a floating gate pattern, to the embodiments illustrated in FIG. 1. Thus, unnecessarily duplicative descriptions of elements shared in FIG. 1 and FIG. 10 are omitted below.

Referring to FIG. 10, floating gate patterns 214b are disposed between isolation layer patterns 207 and partially overlap the isolation layer patterns. The floating gate pattern 214b has an upper surface that is disposed higher than an upper surface of the isolation layer patterns 207. In particular, the floating gate patterns 214b partially cover the upper surface of the isolation layer patterns 207.

Similar to the embodiments illustrated in FIG. 1, a dielectric layer pattern 220 is disposed in contact with the floating gate patterns 214b and the isolation layer patterns 207. However, according to the illustrated embodiments, the area of the dielectric layer pattern 220 in contact with the floating gate pattern 214b is greater than the area of the dielectric layer pattern 116a (FIG. 1) in contact with the floating gate pattern 114a (FIG. 1). Thus, the embodiments illustrated in FIG. 10 may have an improved coupling ratio compared to the embodiments illustrated in FIG. 1.

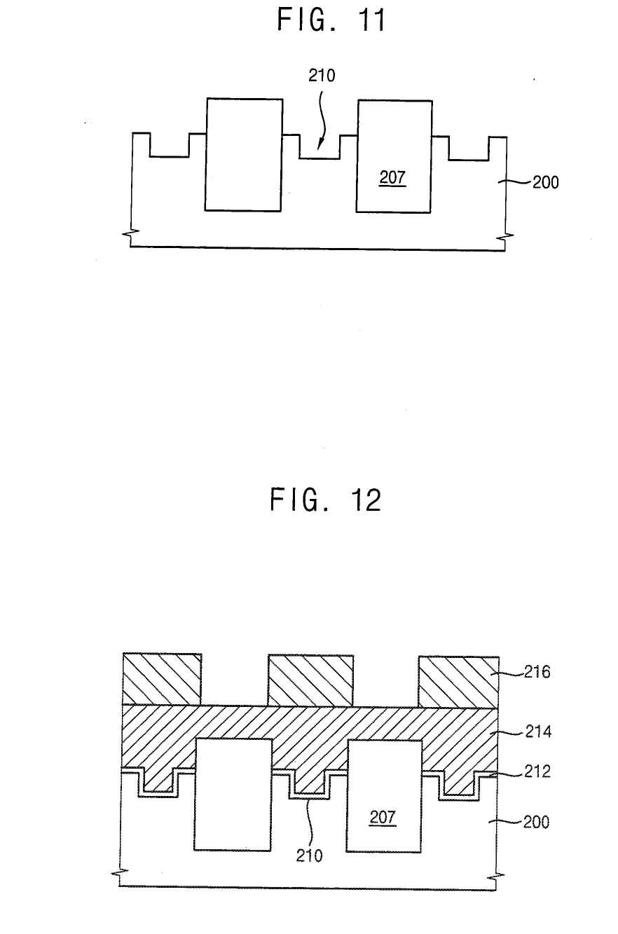

FIGS. 11 to 13 are sectional diagrams illustrating a method of manufacturing the non-volatile memory device of FIG. 10.

Referring to FIG. 11, processes substantially identical to those illustrated with reference to FIGS. 2 to 6 are carried out to form an active region having active trenches 210. Unlike the embodiments illustrated in FIG. 1, the isolation layer patterns 207 shown in FIG. 11 are essentially completed after the process illustrated in FIG. 2 is performed. In other words, the isolation layer patterns 207 are not partially etched after forming preliminary floating gate patterns.

In addition, the floating gate pattern 214b (FIG. 10) is not self-aligned in a gap between the isolation layer patterns 207, which is different from the embodiments illustrated in FIG. 1. Thus, it is not necessary to form a first hard mask pattern having an upper surface that is higher than an upper surface of the floating gate pattern 214b. As a result, the isolation layer patterns 207 have an upper surface that is lower than upper surfaces of the preliminary isolation layer patterns 106 illustrated in FIG. 1.

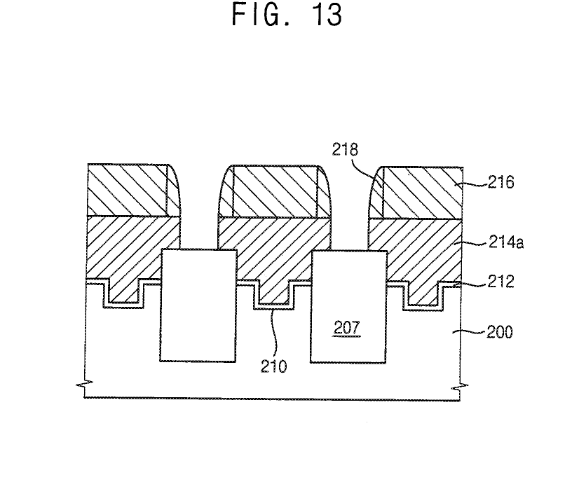

Referring to FIG. 12, a tunnel oxide layer 212 is formed on surfaces of the active region. The semiconductor substrate 200 may be thermally oxidized to form the tunnel oxide layer 212. Although a thickness of the tunnel oxide layer 212 varies in accordance with characteristics of a transistor, the tunnel oxide layer 212 preferably has a thickness of about 50 Å to about 200 Å.

A first conductive layer 214 is then formed on the isolation layer patterns 207 and the tunnel oxide layer 212. The first conductive layer 214 may include polysilicon doped with impurities.

A second hard mask pattern 216 is formed on the first conductive layer 214. The second hard mask pattern 216 may include silicon nitride. The second hard mask pattern 216 has a linear shape that extends lengthwise in a first direction on the active region.

Referring to FIG. 13, second spacers 218 are formed on a sidewall of the second hard mask pattern 216. The second spacers 218 may include silicon nitride. Thus, a masked area of the upper surface of the first conductive layer 214 is increased as much as a width of the second spacers 218 so that a misalignment margin in etching the first conductive layer 214 is increased.

The first conductive layer 214 is partially etched using the second hard mask pattern 216 and the second spacers 218 as an etching mask until the isolation layer patterns 207 are exposed to form a preliminary floating gate pattern 214a. The preliminary floating gate pattern 214a partially covers upper surfaces of the isolation layer patterns 207.

After completing the above-mentioned etching process, an upper side surface of the preliminary floating gate pattern 214a is exposed. Thus, unlike the embodiments illustrated in FIG. 1, after the preliminary floating gate pattern 214a is formed it is not necessary to carry out the process for partially removing the isolation layer patterns 207.

Referring now to FIG. 10, the second hard mask pattern 216 and the second spacers 218 are removed by a wet etching process using a phosphorous acid solution to expose the preliminary floating gate pattern 214a.

A dielectric layer (not shown) is formed on the preliminary floating gate pattern 214a. A second conductive layer (not shown) is then formed on the dielectric layer. A third hard mask pattern 224 is formed on the second conductive layer. Here, the third hard mask pattern 224 has a function substantially identical to that of the second hard mask pattern 120 illustrated in FIG. 1.

The second conductive layer, the dielectric layer, and the preliminary floating gate pattern 214a are sequentially etched using the third hard mask layer pattern 224 as an etching mask to form a floating gate pattern 214b, a dielectric layer pattern 220, and a control gate pattern 222. These processes are substantially identical to those illustrated with reference to FIGS. 1 and 9.

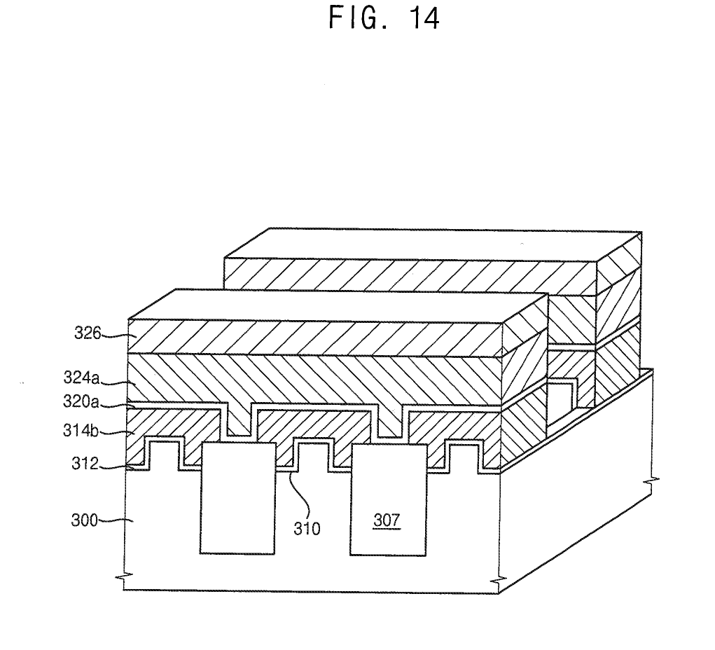

FIG. 14 is a perspective diagram illustrating a non-volatile memory device in accordance with some other embodiments of the invention.

Referring to FIG. 14, a non-volatile memory device includes a semiconductor substrate 300 divided into field regions and active regions. In particular, isolation trenches are formed at a surface portion of the semiconductor substrate 300. The isolation trenches are filled with isolation layer patterns 307 to define the field regions and the active regions. Here, the isolation layer patterns 307 may include silicon oxide. In particular, active trenches 310 are formed at edge surface portions of the active regions.

The isolation layer patterns 307 and the active regions have linear shapes that extend in a first direction. Furthermore, the active trenches 310 extend in the first direction.

Two active trenches 310 are formed at both edges of the surface portions of the active regions. Side surfaces of the isolation layer patterns 307 are exposed by the active trenches 310. Thus, the active regions have a protruding central portion that increases an effective width of the active region.

Furthermore, the isolation layer patterns 308 have an upper surface that is disposed substantially coplanar with an upper surface of the active region.

A tunnel oxide layer 312 is disposed on the active region. The tunnel oxide layer 312 may include silicon oxide. Since the active trenches 310 are provided in the active region, the tunnel oxide layer 312 has a greater area than that of a tunnel oxide layer that is formed on a flat active region. Thus, when charges are inputted/outputted into/from a floating gate pattern 314b from the semiconductor substrate 300 to perform programming process or erasing process of the flash memory device, a sufficient F-N tunneling effect is generated.

The floating gate pattern 314b is disposed on the tunnel oxide layer 312 to fill up the active trench 310. The floating gate pattern 314b may include polysilicon doped with impurities. The floating gate pattern 314b has an upper surface that is higher than that of the isolation layer patterns 307.

A dielectric layer pattern 320a is disposed on the floating gate pattern 314a and on the isolation layer patterns 307. The dielectric layer pattern 320a may have a stacked structure that includes silicon oxide/silicon nitride/silicon oxide. Alternatively, the dielectric layer pattern 320a may include a material having a high dielectric constant. The material having a high dielectric constant may include a metal oxide material. Examples of the metal oxide material include HfO₂, ZrO₂, Ta₂O₅, Y₂O₃, Nb₂O₅, Al₂O₃, TiO₂, CeO₂, In₂O₃, RuO₂, MgO, SrO, B₂O₃, SnO₂, PbO, PbO₂, Pb₃O₄, V₂O₃, La₂O₃, Pr₂O₃, Sb₂O₃, Sb₂O₅, CaO, etc. The metal oxide materials may be used alone or in combination with other metal oxide materials and other layers.

A control gate pattern 324a is disposed on the dielectric layer pattern 320a. The control gate pattern 324a may include polysilicon doped with impurities, a metal, etc. The control gate pattern 324a has a linear shape and extends in the second direction.

A hard mask pattern 326 is disposed on the control gate pattern 324a. The hard mask pattern 326 may include silicon nitride.

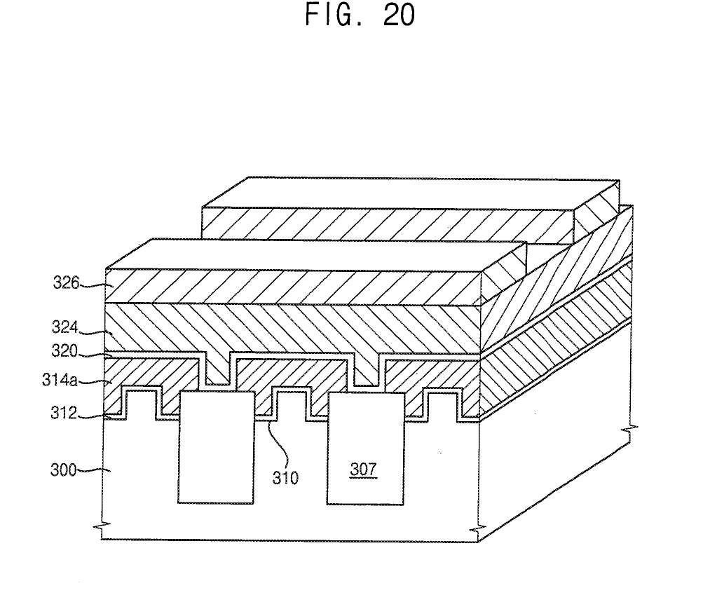

FIGS. 15 to 19 are sectional diagrams illustrating a method of manufacturing the non-volatile memory device of FIG. 14. FIG. 20 is a perspective diagram illustrating the method of manufacturing the non-volatile memory device of FIG. 14.

Referring to FIG. 15, processes substantially identical to those illustrated with reference to FIG. 2 are carried out to form a first hard mask pattern 302 and preliminary isolation layer patterns 306.

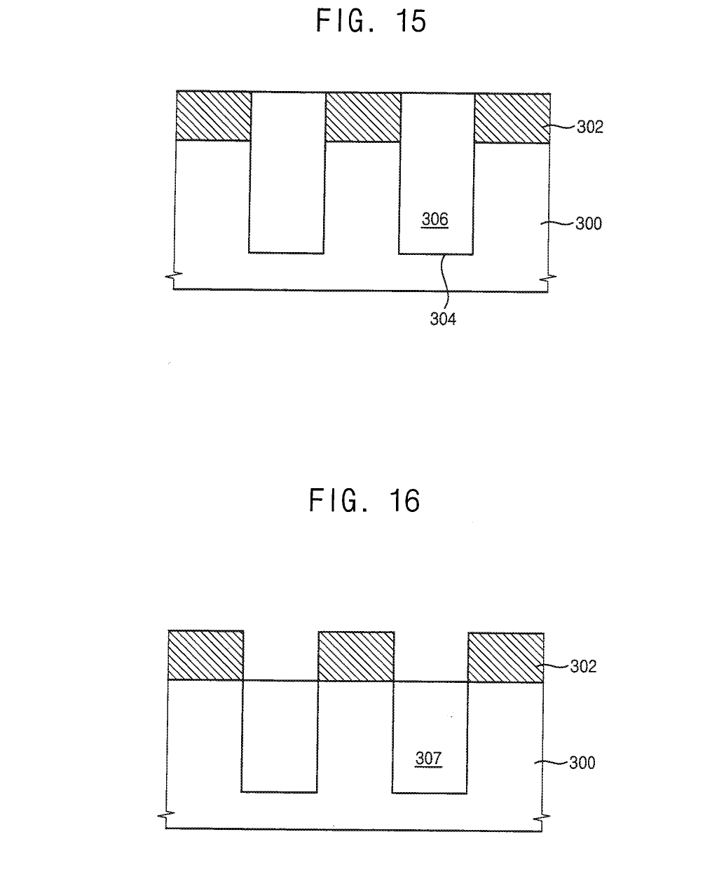

Referring to FIG. 16, the preliminary isolation layer patterns 306 are partially etched until side surfaces of the first hard mask pattern 302 are exposed to form isolation layer patterns 307 having upper surfaces that are substantially coplanar with upper surfaces of the semiconductor substrate 300. Here, the preliminary isolation layer patterns 306 may be partially removed by a wet etching process using a hydrofluoric acid solution for forming the isolation layer patterns 307, so that the isolation layer patterns 307 have a thickness that is less than that of the preliminary isolation layer patterns 306.

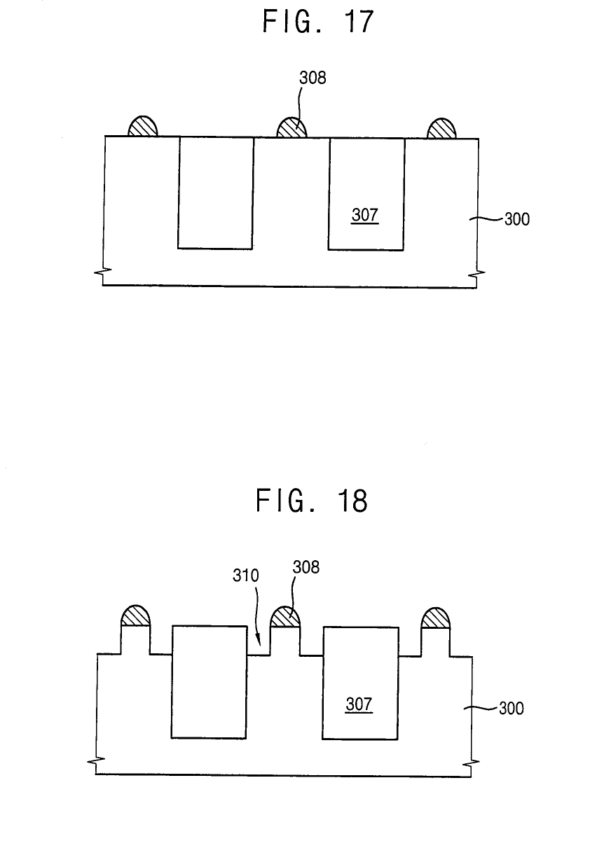

Referring to FIG. 17, the first hard mask pattern 302 is anisotropically etched until the semiconductor substrate 300 is partially exposed to form a second hard mask pattern 308. Here, the first hard mask pattern 302 may be partially removed by a wet etching process using a phosphorous acid solution. Furthermore, to prevent the first hard mask pattern 302 from being completely removed, it is very important to optimize etching conditions.

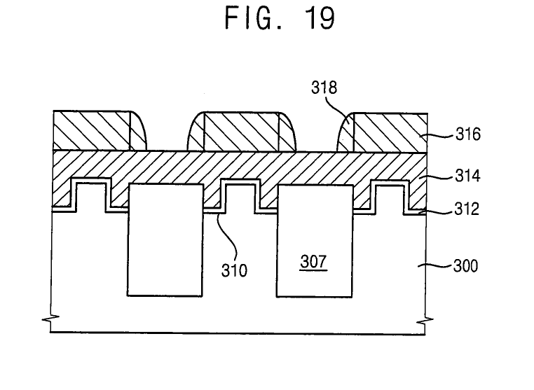

Referring to FIG. 18, the semiconductor substrate 300 is partially etched using the second hard mask pattern 308 as an etching mask to form the active trenches 310, thereby increasing the surface area of the active region.

Since the active trenches 310 are formed at the both edge portions of the active region adjacent to the isolation layer patterns 307, the active region has a protruded central portion so that the active region has an increased effective area.

Referring to FIG. 19, the second hard mask pattern 308 is removed to expose the active region. Here, the second hard mask pattern 308 may be removed by a wet etching process using a phosphorous acid solution.

A tunnel oxide layer 312 is formed on the exposed active region. The semiconductor substrate 300 may be thermally oxidized to form the tunnel oxide layer 312. Although a thickness of the tunnel oxide layer 312 varies in accordance with characteristics of a transistor, the tunnel oxide layer 312 preferably has a thickness of about 50 Å to about 200 Å.

A first conductive layer 314 is then formed on the isolation layer patterns 307 to fill up a gap between the isolation layer patterns 307. The first conductive layer 314 may include polysilicon doped with impurities.

A third hard mask pattern 316 is then formed on the first conductive layer 314. The third hard mask pattern 316 may include silicon nitride. The third hard mask pattern 316 is positioned on the active region and also has a linear shape that extends in the first direction.

Spacers 318 are formed on a sidewall of the third hard mask pattern 316. The spacers 318 may include silicon nitride.

Referring to FIG. 20, the first conductive layer 314 is etched using the third hard mask pattern 316 and the spacers 318 as an etching mask until the isolation layer patterns 307 are exposed to form a preliminary floating gate pattern 314a. Here, the preliminary floating gate patterns 314a are disposed to partially cover the upper surfaces of the isolation layer patterns 307.

The third hard mask pattern 316 and the spacers 318 are removed by a wet etching process using a phosphorous acid solution to expose an upper surface and upper side surfaces of the preliminary floating gate pattern 314a.

A dielectric layer 320 is formed on the preliminary floating gate pattern 314a. The dielectric layer 320 may include silicon oxide/silicon nitride/silicon oxide. Alternatively, the dielectric layer 320 may include a metal oxide material having a high dielectric constant. Examples of the metal oxide material include HfO₂, ZrO₂, Ta₂O₅, Y₂O₃, Nb₂O₅, Al₂O₃, TiO₂, CeO₂, In₂O₃, RuO₂, MgO, SrO, B₂O₃, SnO₂, PbO, PbO₂, Pb₃O₄, V₂O₃, La₂O₃, Pr₂O₃, Sb₂O₃, Sb₂O₅, CaO, etc. These metal oxide materials may be used alone or in combination with other metal oxide materials or layers that were described above.

A second conductive layer 324 and a fourth hard mask pattern 326 are sequentially formed on the dielectric layer 320.

Referring now to FIG. 14, the second conductive layer 324, the dielectric layer 320, and the preliminary floating gate pattern 314a are sequentially etched using the fourth hard mask pattern 326 as an etching mask to form a floating gate pattern 314b, a dielectric layer pattern 320a, and a control gate pattern 324a. Here, the floating gate pattern 314a has an isolation shape in the active region. Furthermore, the dielectric layer pattern 320a and the control gate pattern 324a have linear shapes that are substantially perpendicular to the active region.

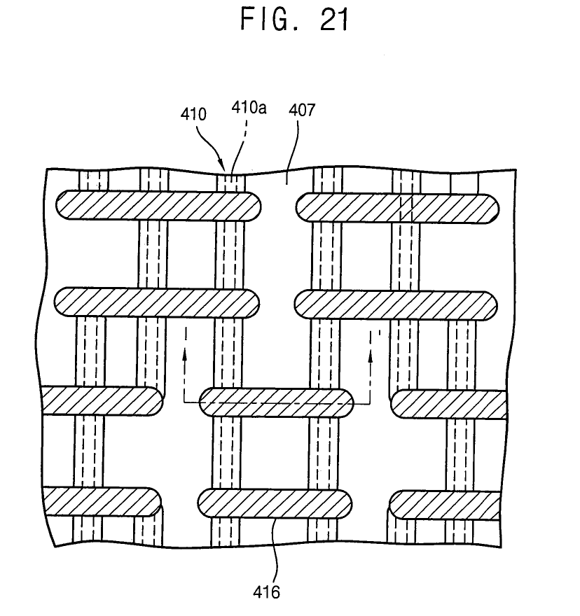

FIG. 21 is a plan diagram illustrating a gate structure of a transistor in an SRAM device in accordance with some embodiments of the invention. FIG. 22 is a sectional diagram taken along the line I-I′ of FIG. 21.

Referring to FIGS. 21 and 22, a transistor of the illustrated embodiments includes a semiconductor substrate 400 divided into field regions and active regions 410. In particular, isolation trenches are formed at a surface portion of the semiconductor substrate 400. The isolation trenches are filled with isolation layer patterns 407 to define the field regions and the active regions 410. The active regions 410 are isolated from adjacent active regions. Active trenches 410a are formed at a central surface portion of the active regions. The active trenches 410a extend in a direction that is substantially parallel to a lengthwise direction of a channel layer in the transistor.

At least one active trench 410a may be provided to a central portion of the active region. Since the area of the active region 410 is very small, it is difficult to provide one active region with several active trenches 410a. Thus, in the illustrated embodiments, one active trench 410a is disposed in each active region. Thus, edge portions of the active region between the isolation layer patterns 407 and the active trench 410a protrude upwardly so that the effective width of the active region is increased.

A gate insulation layer 412 is disposed on the upper surfaces of the active region as well as on a side surface and a bottom surface of the active trench 410a. The gate insulation layer 412 may include silicon oxide. Since the active trench 410a is provided in the active region, the gate insulation layer 412 has a greater area than that of a gate insulation layer that is formed on a flat active region. Thus, a transistor may have a rapid operation speed because an amount of a current flow per time unit is increased.

A gate pattern 414a is disposed on the gate insulation layer 412 and the isolation layer patterns 407. The gate pattern 414a has an upper surface that is higher than an upper surface of the isolation layer patterns 407. The gate pattern 414a is arranged in a direction that is substantially perpendicular to the active trenches 410a.

A hard mask pattern 416 is disposed on the gate pattern 414a. The hard mask pattern 416 may include silicon nitride.

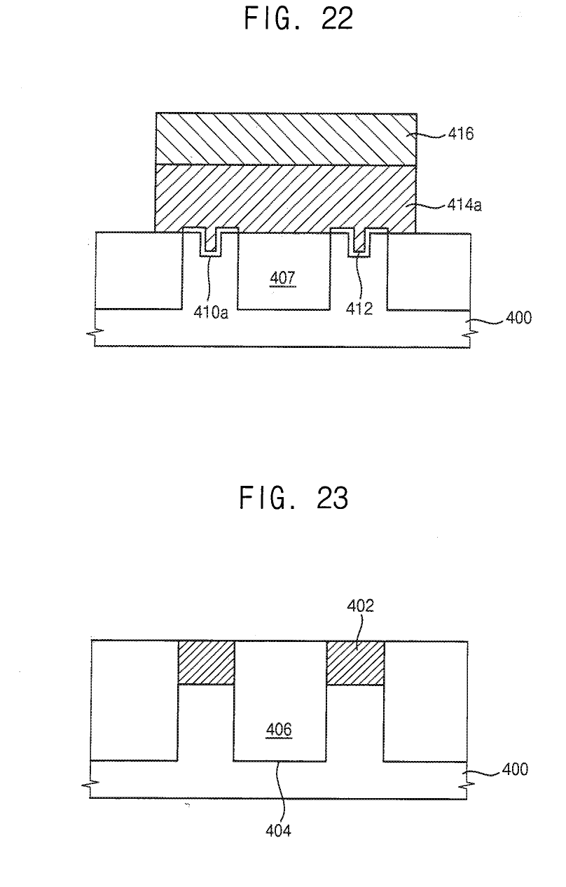

FIGS. 23 to 26 are sectional diagrams illustrating a method of manufacturing the gate structure of FIG. 22.

Referring to FIG. 23, a buffer oxide layer (not shown) is formed on the semiconductor substrate 400. A first hard mask pattern 402 for selectively masking the active region 410 is formed on the buffer oxide layer. The first hard mask pattern 402 functions as an etching mask for forming the isolation trenches. The first hard mask pattern 402 may include silicon nitride. The first hard mask pattern 102 includes several regions that are separated from one another.

The buffer oxide layer and the semiconductor substrate 400 are selectively etched using the first hard mask pattern 402 as an etching mask to form the isolation trenches 404. To cure etching damages, an oxide layer (not shown) is formed on inner surfaces of the isolation trenches 404.

An isolation layer (not shown) is formed on the oxide layer and the first hard mask pattern 402 to fill up the isolation trenches 404.

The isolation layer is planarized by a chemical mechanical polishing (CMP) process until the hard mask pattern 402 is exposed to form preliminary isolation layer patterns 406 in the isolation trenches 404.

Referring to FIG. 24, processes substantially identical to those illustrated with reference to FIGS. 4 to 6 are carried out to form active trenches 410a at a central portion of the active region 410. Thus, the active region has protruded edge portions adjacent to the preliminary isolation layer patterns 406 so that the active region 410 may have an increased effective width compared to that of an active region 410 having a flat upper surface.

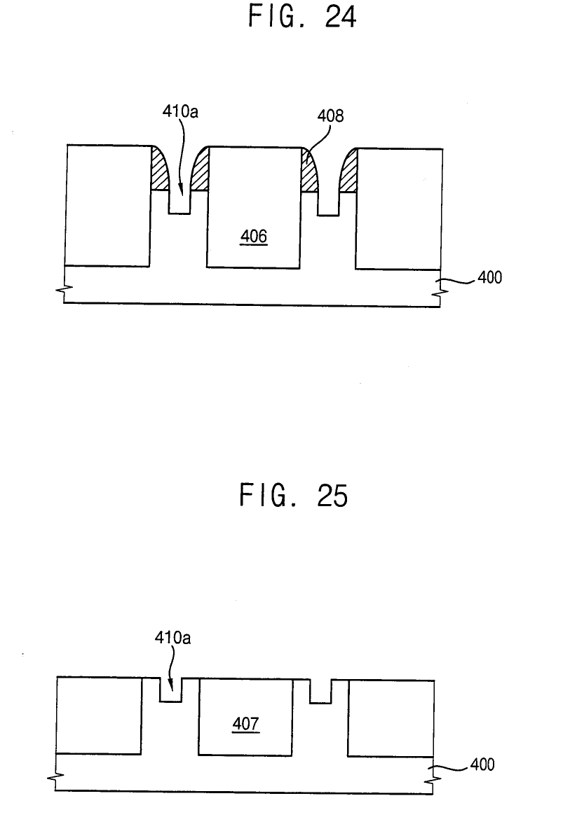

Referring to FIG. 25, the spacers 408, which are used as a mask pattern in etching the semiconductor substrate 400, are removed to expose the active region 410. Here, the process for removing the spacers 408 may be carried out by a wet etching process using a phosphorous acid solution.

The preliminary isolation layer patterns 406 are then partially etched to form isolation layer patterns 407 having an upper surface that is substantially coplanar with the upper surface of the semiconductor substrate 400. Here, the preliminary isolation layer patterns 407 may have an upper surface that is higher than that of the active region 410. Alternatively, the process for etching the preliminary isolation layer patterns 406 may be carried out before removing the spacers 408.

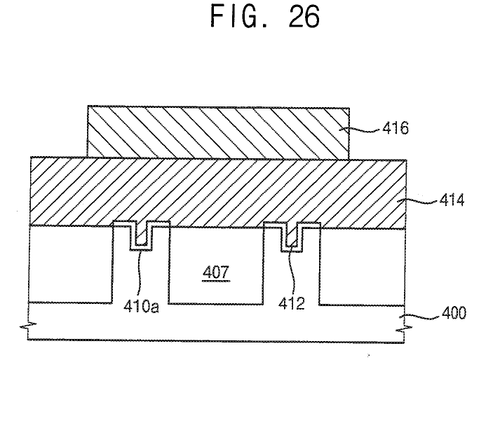

Referring to FIG. 26, the gate insulation layer 412 is formed on the active region 410. A first conductive layer 414 is then formed on the isolation layer patterns 407 and the gate insulation layer 412 to fill up a gap between the isolation layer patterns 407. The first conductive layer 414 may include polysilicon doped with impurities.

A second hard mask pattern 416 is then formed on the first conductive layer 414. The second hard mask pattern 416 extends in a direction that is substantially perpendicular to a lengthwise direction of the active region 410.

Referring now to FIG. 22, the first conductive layer 414 is etched using the second hard mask pattern 416 as an etching mask to form a gate electrode 414a. In addition, source/drain regions (not shown) may be formed between the gate electrode 414a to complete the transistor of the illustrated embodiments.

FIG. 27 is a sectional diagram illustrating a gate structure of a transistor in accordance with some embodiments of the invention.

Referring to FIG. 27, a transistor includes a semiconductor substrate 500 divided into a field region and an active region. In particular, isolation trenches are formed at a surface portion of the semiconductor substrate 500. The isolation trenches are filled with isolation layer patterns 507 to define the field region and the active region. The active region has an isolated shape.

Active trenches 510 are formed at a central surface portion of the active region. The active trenches 510 enclose an edge portion of the active region. Side surfaces of the isolation layer patterns 507 are exposed by the active trenches 510. Thus, the active region has an upwardly protruding central portion so that the effective width of the active region is increased.

A gate insulation layer 512 is formed on an upper surface of the active region, a side surface of the active trench 510, and a bottom surface of the active trench. Since the active trench 510 is provided to the active region, the gate insulation layer 512 has a greater area than that of a gate insulation layer that is formed on a flat active region. Thus, an amount of a current flow per time unit is increased during operation of the transistor so that the transistor may have a rapid operation speed.

A gate pattern 514a is formed on the gate insulation layer 512 and the isolation layer patterns 507. The gate pattern 514a has an upper surface that is positioned higher than that of an upper surface of the isolation layer pattern 507. The gate pattern 514a is arranged in a direction that is substantially perpendicular to the active trenches 510.

A hard mask pattern 516 is formed on the gate pattern 514a. The hard mask pattern 516 may include silicon nitride.

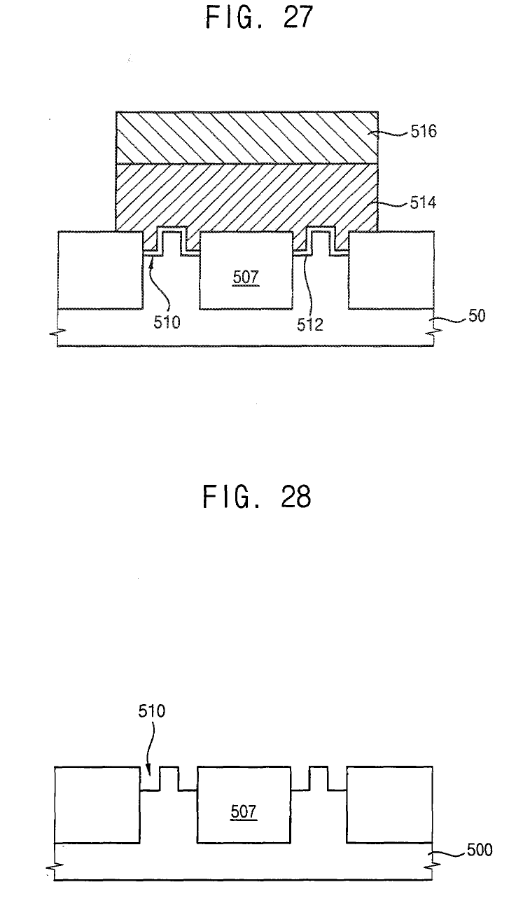

FIG. 28 is a sectional diagram illustrating a method of forming the gate structure in FIG. 27.

Processes substantially identical to those illustrated with reference to FIG. 23 are performed to form a first hard mask pattern (not shown) and preliminary isolation layer patterns (not shown).

Referring to FIG. 28, processes substantially identical to those illustrated with reference to FIGS. 16 to 18 are carried out to form the active region having the active trenches 510 adjacent to the isolation layer patterns 507. The active region has an upwardly protruding central portion so that the active region may have an increased effective width.

Referring now to FIG. 27, the gate insulation layer 512 is formed on the active region. A first conductive layer (not shown) is then formed on the isolation layer patterns 507 and the active region to fill up the gate trenches 510. The first conductive layer may include polysilicon doped with impurities.

A second hard mask pattern 516 is then formed on the first conductive layer. The second hard mask pattern 516 extends in a direction substantially perpendicular to a lengthwise direction of the active region.

The first conductive layer is then etched using the second hard mask pattern 516 as an etching mask to form a gate pattern 514. In addition, source/drain regions (not shown) may be formed between the gate patterns 514 to complete the transistor.

According to embodiments of the invention, the active region has an increased effective area due to the active trenches so that the semiconductor device including the non-volatile memory device and the gate structure may have improved operational characteristics.

The invention may be practiced in many ways. What follows are exemplary non-limiting descriptions of some embodiments of the invention.

According to some embodiments, a non-volatile memory device includes a substrate that is divided into a field region and an active region by isolation layer patterns. The active region has an active trench for increasing an effective area of the active region. A tunnel oxide layer is formed on the active region. A floating gate pattern is formed on the tunnel oxide layer to fill up the active trench. A dielectric layer pattern is formed on the floating gate pattern. A control gate pattern is formed on the dielectric layer pattern.

According to some embodiments, a method of manufacturing a non-volatile memory device includes forming isolation layer patterns at a surface portion of a substrate to define a field region and an active region of the substrate. The method includes partially etching the active region to form an active trench at a surface portion of the active region. The method includes forming a tunnel oxide layer on the active region. The method includes forming preliminary floating gate pattern on the tunnel oxide layer to fill up the active trench. A dielectric layer is formed on the preliminary floating gate pattern. A conductive layer is formed on the dielectric layer. The conductive layer, the dielectric layer and the preliminary floating gate pattern are then patterned to form a control gate pattern, a dielectric layer pattern and a floating gate pattern.

According to some embodiments, a method of manufacturing a non-volatile memory device includes forming isolation layer patterns at a surface portion of a substrate to define a field region and an active region of the substrate. The isolation layer patterns protrude from the substrate. A spacer is formed on a sidewall of the isolation layer patterns. The active region is partially etched using the spacer to form an active trench at a surface portion of the active region. A tunnel oxide layer is formed on the active region. A preliminary floating gate pattern is formed on the tunnel oxide layer to fill up the active trench. A dielectric layer is formed on the preliminary floating gate pattern. A conductive layer is formed on the dielectric layer. The conductive layer, the dielectric layer and the preliminary floating gate pattern are then patterned to form a control gate pattern, a dielectric layer pattern and a floating gate pattern.

According to some embodiments, a method of manufacturing a non-volatile memory device includes forming a first hard mask pattern on an active region of a substrate. Isolation layer patterns are formed at a surface portion of a field region of the substrate. Here, the isolation layer patterns has a surface that is positioned on a plane substantially identical to or lower than that on which a surface of the substrate is positioned. The first hard mask pattern is partially removed to form a second hard mask pattern partially exposing the active region. The active region is partially etched using the second hard mask pattern to form an active trench at a surface portion of the active region. A tunnel oxide layer is formed on the active region. A preliminary floating gate pattern is formed on the tunnel oxide layer to fill up the active trench. A dielectric layer is formed on the preliminary floating gate pattern. A conductive layer is formed on the dielectric layer. The conductive layer, the dielectric layer and the preliminary floating gate pattern are patterned to form a control gate pattern, a dielectric layer pattern and a floating gate pattern.

According to some embodiments, a gate structure includes a substrate that is divided into a field region and an active region by isolation layer patterns. The active region has an active trench for increasing an effective area of the active region. A gate insulation layer is formed on the active region. A gate pattern is formed on the tunnel oxide layer to fill up the active trench.

According to some embodiments, a method of forming a gate structure of a transistor includes forming isolation layer patterns at a surface portion of a substrate to define a field region and an active region of the substrate. The active region is partially etched to form an active trench at a surface portion of the active region. A gate insulation layer is formed on the active region. A gate pattern is formed on the gate insulation layer to fill up the active trench.

According to embodiments of the invention, since the active region has the active trench, the active region may have an increased effective width. Thus, a contact area between the floating gate pattern and the active region in the non-volatile memory device is widened so that an F-N tunneling effect may be sufficiently generated. As a result, the non-volatile memory device may have improved operational characteristics.

Furthermore, since the gate structure of the transistor is formed on the active region having the increased effective width, a current flow in operating the transistor may be increased so that a semiconductor device including the transistor may be a rapid operation speed.

Having described exemplary embodiments of the invention, it is noted that modifications and variations can be made by persons skilled in the art in light of the above teachings. It is therefore to be understood that changes may be made to the particular embodiments disclosed above that nevertheless still fall within the scope and the spirit of the invention as defined in the attached claims.

1. A non-volatile memory device comprising:
a substrate including a field region and an active region that are defined by isolation layer patterns, the active region having an active trench;
a tunnel oxide layer disposed on a surface of the active region and a surface of the active trench;
a floating gate pattern disposed on the tunnel oxide layer, the floating gate pattern filling the active trench;
a dielectric layer disposed on a surface of the floating gate pattern and on surfaces of the isolation layer patterns; and
a control gate pattern disposed on the dielectric layer pattern,
wherein the active trench is disposed at an edge surface portion of the active region adjacent to one of the isolation layer patterns.

2. The non-volatile memory device of claim 1, wherein a side surface of the one of the isolation layer patterns is exposed by the active trench.

3. A non-volatile memory device comprising:
a substrate including a field region and an active region that are defined by isolation layer patterns, the active region having an active trench;
a tunnel oxide layer disposed on a surface of the active region and a surface of the active trench;
a floating gate pattern disposed on the tunnel oxide layer, the floating gate pattern filling the active trench;
a dielectric layer disposed on a surface of the floating gate pattern and on surfaces of the isolation layer patterns; and
a control gate pattern disposed on the dielectric layer pattern, wherein the active region comprises a protruded central portion spaced apart from the isolation layer patterns.

4. A gate structure of a transistor, the gate structure comprising:
a substrate including a field region and an active region that are defined by isolation layer patterns, the active region having an active trench;
a gate insulation layer disposed on the active region; and
a gate pattern that fills the active trench, the gate pattern disposed on the tunnel oxide layer,
the active trench disposed at an edge surface portion of the active region between the isolation layer patterns.
